(19) United States
(12) Patent Application Publication
(10) Pub. No.: US 2011/0184687 A1
(43) Pub. Date: Jul. 28, 2011

(54) TEST APPARATUS AND TEST METHOD

(75) Inventors: Tadashi MORITA, Gunma (JP); Mamoru HIRAIDE, Saitama (JP)

(73) Assignee: ADVANTEST CORPORATION, Tokyo (JP)

(21) Appl. No.: 12/693,095

(22) Filed: Jan. 25, 2010

(51) Int. Cl. G06F 19/00; G01R 31/00

(52) U.S. Cl. 702/118

(57) ABSTRACT

A test apparatus for testing a device under test includes a test module that exchanges signals with the device under test to test the device under test, a test controller that includes a processor and a memory, where the test controller controls the test module, and a network that transfers communication packets between the test module and the test controller. Here, the test controller includes a receiving section that receives an interrupt packet requesting an interrupt to the test controller, from the test module via the network, a memory writing section that writes interrupt information included in the interrupt packet into the memory, and an interrupt notifying section that notifies the processor of the interrupt to cause the processor to reference the interrupt information written into the memory.

### BACKGROUND

1. Technical Field

The present invention relates to a test apparatus and a test method.

2. Related Art

A known test apparatus designed to test a device under test such as a semiconductor chip includes a plurality of test circuits (for example, see Patent Documents 1 and 2). In such a test apparatus, the plurality of test circuits preferably operate in synchronization with each other.

Patent Document 1: International Publication No. 2003/062843

Patent Document 2: Japanese Patent Application Publication No. 2007-052028

Here, the test circuits included in the test apparatus operate in accordance with programs, sequences and the like supplied thereto in advance. The test apparatus controls the test circuits to operate in synchronization with each other by starting and stopping executing the programs and the like in synchronization.

When the test apparatus is configured to perform a variety of tests, however, synchronizing the execution start timings of the programs at the respective test circuits may not be sufficient to control the test circuits to operate in synchronization with each other. For example, there maybe a case where a certain step is desirably triggered in response to detection of a failure or process resume condition at a predetermined test circuit while a program is being executed. Thus, it is desired to realize a test apparatus that is capable of performing a variety of tests.

### SUMMARY

Therefore, it is an object of an aspect of the innovations herein to provide a test apparatus and a test method which are capable of overcoming the above drawbacks accompanying the related art. The above and other objects can be achieved by combinations described in the independent claims. The dependent claims define further advantageous and exemplary combinations of the innovations herein.

According to an aspect related to the innovations herein, one exemplary test apparatus for testing a device under test may include a test module that exchanges signals with the device under test to test the device under test, a test controller that includes a processor and a memory, where the test controller controls the test module, and a network that transfers communication packets between the test module and the test controller. Here, the test controller includes a receiving section that receives an interrupt packet requesting an interrupt to the test controller, from the test module via the network, a memory writing section that writes interrupt information included in the interrupt packet into the memory, and an interrupt notifying section that notifies the processor of the interrupt to cause the processor to reference the interrupt information written into the memory.

The summary clause does not necessarily describe all necessary features of the embodiments of the present invention. The present invention may also be a sub-combination of the features described above. The above and other features and advantages of the present invention will become more apparent from the following description of the embodiments taken in conjunction with the accompanying drawings.

### BRIEF DESCRIPTION OF THE DRAWINGS

FIG. 1 illustrates an exemplary configuration of a test apparatus 100 relating to an embodiment of the present invention, together with devices under test 10.

FIG. 2 illustrates an exemplary configuration of a test controller 130 of the test apparatus 100 relating to the embodiment of the present invention.

FIG. 3 is a flow chart illustrating the operations of the test apparatus 100 relating to the embodiment of the present invention.

FIG. 4 illustrates, as an example, interrupt information stored on a memory 220 of the test apparatus 100 relating to the embodiment of the present invention.

### DESCRIPTION OF EXEMPLARY EMBODIMENTS

Some aspects of the invention will now be described based on the embodiments, which do not intend to limit the scope of the present invention, but exemplify the invention. All of the features and the combinations thereof described in the embodiment are not necessarily essential to the invention.

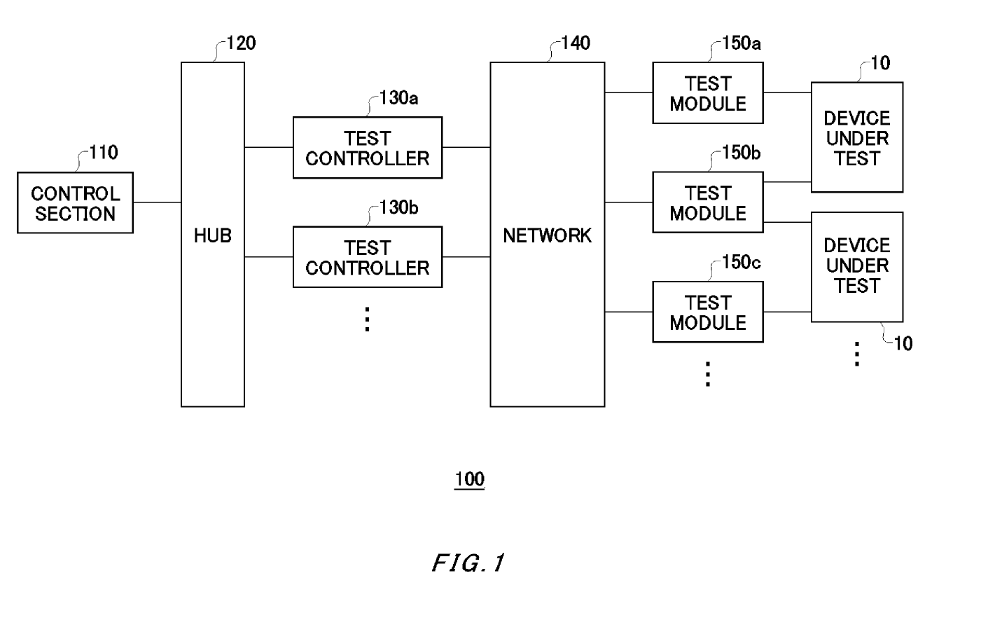

FIG. 1 illustrates an exemplary configuration of a test apparatus 100 relating to an embodiment of the present invention, together with devices under tests 10. The test apparatus 100 is designed to test at least one device under test 10, which is, for example, an analog circuit, a digital circuit, an analog/digital mixed circuit, a memory, and a system on chip (SOC). The test apparatus 100 may test a plurality of devices under test 10 individually or in parallel. The test apparatus 100 includes a control section 110, a hub 120, a test controller 130, a network 140, and a test module 150.

The control section 110, which is a system controller for controlling the entire system, for example, is configured to control the entire test apparatus 100. For example, the control section 110 controls the test controller 130 and the test module 150 in accordance with a program, an instruction or the like supplied by a user or the like. More specifically, the control section 110 may acquire a test program from an external computer or storage device such as a workstation or from a user's input, and use the acquired program to control the operation of the test controller 130. The control section 110 may transmit a program and/or a control instruction corresponding to a test, to a corresponding test controller 130 via the hub 120.

The hub 120 is a network that communicatively connects the control section 110 to at least one test controller 130. The hub 120 may relay the communication through a general-purpose or dedicated high-speed serial bus or the like. The general-purpose high-speed serial bus may be compatible with, for example, Eathernet®, USB, Serial RapidIO, or the like.

The test controller 130 executes a test control program to control the test module 150. The test controller 130 may control the test module 150 in accordance with the control instruction and/or program supplied form the control section 110. More specifically, the test controller 130 may generate a control instruction to control the operation of the test module 150 in correspondence with a test. The test apparatus 100 may include a plurality of test controllers 130 for the purpose of testing a plurality of devices under test 10. Each test controller 130 may independently perform a plurality of tests.

The test controller 130 may be used to test one or more devices under test 10. The test controller 130 may exchange data with at least one test module 150 via the network 140. The test controller 130 may prestore, onto each test module 150, a predetermined test program, a data pattern, or the like corresponding to a test. The test controller 130 may be a site controller that is designed to control tests by terminal groups into which the terminals of a plurality of test modules 150a-150c are divided.

The network 140 transfers communication packets between the test module 150 and the test controller 130. The network 140 may communicatively connect the test controller 130 to one or more appropriate test modules 150 depending on a plurality of tests to be performed, so that the tests are performed with an appropriate number of test modules 150. The network 140 may use a plurality of bus switches to establish connections only between the test controller 130 and the test modules 150 corresponding to the tests.

The test module 150 tests the device under test 10 by communicating signals with the device under test 10. The test apparatus 100 may have a plurality of types of test modules 150 mounted thereon in correspondence with a plurality of types of tests to be performed. In this case, some of the test modules 150 may be digital modules that perform digital tests by exchanging digital signals with the device under test 10 or analog modules that perform analog tests by exchanging analog signals with the device under test 10.

Each test module 150 may be detachably mounted on the test apparatus 100. The test module 150 may operate in accordance with a clock synchronized with the clock of the test apparatus 100. Alternatively, the test module 150 may operate in accordance with a different clock that is separately generated internally or by the device under test 10. The test module 150 exchanges test signals with the device under test 10 via a connector. The connector, for example, includes a motherboard, a performance board, and a socket.

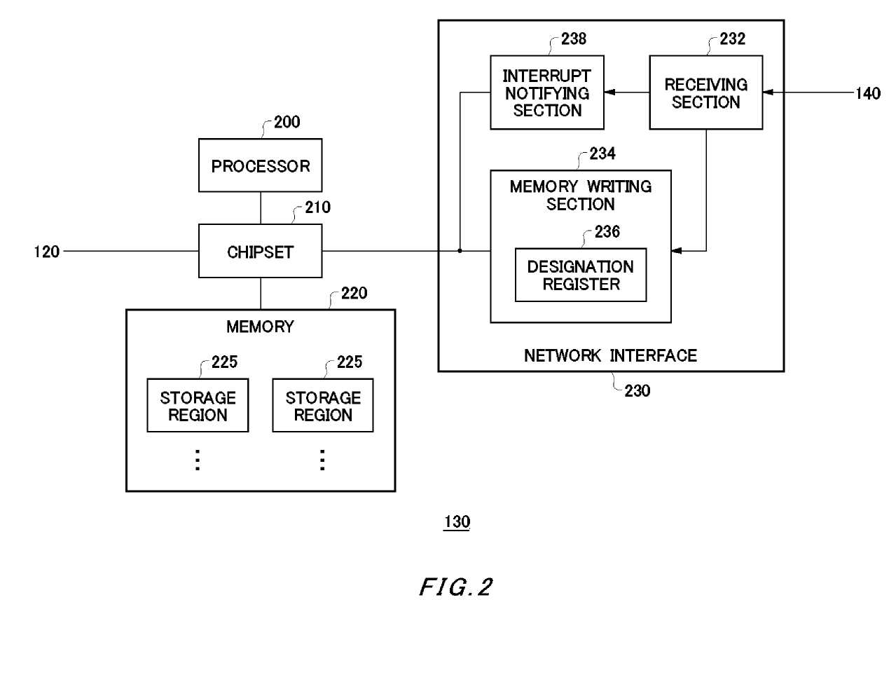

FIG. 2 illustrates an exemplary configuration of the test controller 130 of the test apparatus 100 relating to the embodiment of the present invention. The test controller 130 includes a processor 200, a chipset 210, a memory 220, and a network interface 230.

The processor 200 may be a CPU including an arithmetic logic unit and/or a control unit, and may be in charge of data transfer, data processing, program control, and the like. The processor 200 may transmit/receive a control instruction, a program, and/or data including a test result to/from the control section 110 via the chipset 210 and the hub 120. The processor 200 may also transmit/receive a control instruction, a program, and/or data including a test result to/from a processor included in a different test controller 130 via the hub 120.

The chipset 210 may represent a group of circuits that are connected to the external bus of the processor 200, the memory 220, the network interface 230, and the like to manage data exchange therebetween. The memory 220 stores thereon interrupt information for the test module 150. The memory 220 has a plurality of storage regions 225 for storing the interrupt information.

The network interface 230 has a networking function and connects the test controller 130 to one or more test modules 150 via the network 140. The network interface 230 includes a receiving section 232, a memory writing section 234, and an interrupt notifying section 238.

The receiving section 232 receives via the network 140 from the test module 150 an interrupt packet that requests an interrupt to the test controller 130. The receiving section 232 may transmit the received interrupt packet to the memory writing section 234. The receiving section 232 may also notify the interrupt notifying section 238 of the reception of the interrupt packet.

The memory writing section 234 writes into the memory 220 interrupt information contained in the interrupt packet. When the receiving section 232 receives a plurality of interrupt packets, the memory writing section 234 may sequentially write into the memory 220 a plurality of pieces of interrupt information contained in the plurality of interrupt packets. The memory writing section 234 may include a designation register 236 that designates one of the storage regions 225 of the memory 220 as a target storage region into which the interrupt information is to be written.

The interrupt notifying section 238 notifies the processor 200 of an interrupt to cause the processor 200 to reference the interrupt information written into the memory 220. When notified of an interrupt by the interrupt notifying section 238, the processor 200 references the memory 220 and acquires one or more pieces of interrupt information.

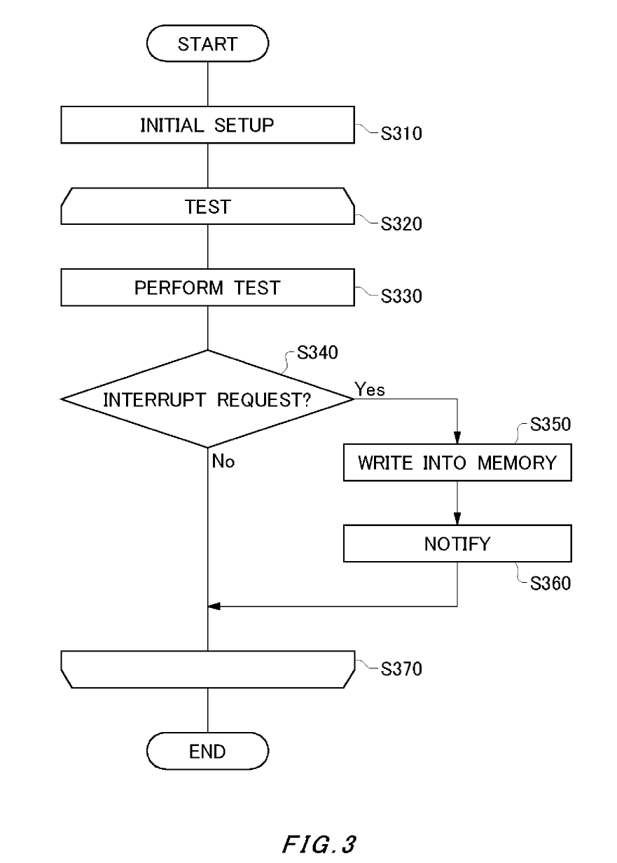

FIG. 3 is a flow chart illustrating the operations of the test apparatus 100 relating to the embodiment of the present invention. The test apparatus 100 is configured in accordance with initial setups such as test parameters (S310). For example, the test apparatus 100 is configured by referring to a test program such that the network 140 connects an appropriate test controller 130 to one or more test modules 150 that are connected to a device under test 10. Alternatively, the test apparatus 100 is configured by referring to a test program such that the network 140 connects one or more appropriate test controllers 130 to one or more test modules 150 that are connected to a plurality of devices under test 10 in order to enable a plurality of tests to be performed in parallel.

During a test, the test apparatus 100 repeatedly performs the loop procedure including the steps S320 to S370 for each test type or each group of one or more instructions of a test program. The one or more test controllers 130 cause the test modules 150 connected thereto via the network 140 to perform tests corresponding to a test program (S330).

For example, the test modules 150 sequentially execute the respective instructions included in the supplied test programs and perform operations corresponding to the instructions. Here, the test program may include a sequence indicating the order of outputting prestored data patterns. The test modules 150 may include a sequencer that orderly outputs the data patterns in accordance with the sequence.

Here, the data pattern may be a single-bit pattern that designates the logic values to be supplied to the pin of the device under test 10 one bit at a time, or a multi-bit pattern that designates the logic values to be supplied to the pin of the device under test 10 predetermined multiple bits at a time. Alternatively, the data pattern may be a packet pattern that designates the logic values to be supplied to the pin of the device under test 10 over a plurality of cycles to realize a predetermined test function.

The test modules 150 may judge whether the devices under test 10 are acceptable by comparing the signals received from the devices under test 10 with an expected value. The test modules 150 may generate the expected value in the same manner as the patterns to be supplied to the devices under test 10.

During a test, the test modules 150 may transmit an interrupt packet requesting an interrupt to the test controllers 130 when a failure occurs, when the test starts, and/or when the test ends. In addition, the test modules 150 may transmit an interrupt packet when a predetermined condition is satisfied, for example, in order to proceed to the next pattern.

The test controllers 130 detect whether the test modules 150 have transmitted an interrupt packet. If the test modules 150 have not transmitted an interrupt packet, the test controllers 130 continues performing the loop procedure including the steps S320 to S370 (S340). When the test controllers 130 receive an interrupt packet from the test modules 150, the receiving section 232 transmits the received interrupt packet to the memory writing section 234. Also, the receiving section 232 notifies the interrupt notifying section 238 of the reception of the interrupt packet or transmits the received interrupt packet to the interrupt notifying section 238.

The memory writing section 234 writes interrupt information into one of the storage regions 225 of the memory 220 that is designated by the designation register 236 as a target storage region into which the interrupt information is expected to be written (S350). In addition, in response to the receiving section 232 receiving the interrupt packet, the interrupt notifying section 238 notifies the processor 200 of the interrupt, to cause the processor 200 to reference the interrupt information written into the memory 220 (S360). Here, the interrupt notifying section 238 may notify the processor 200 of the interrupt to cause the processor 200 to reference the interrupt information after having confirmed that the memory writing section 234 has completed writing the interrupt information.

For example, the memory writing section 234 updates the designation register 236 to switch the target storage region to a different one of the storage regions 225 in response to the interrupt notifying section 238 notifying the processor 200 of the interrupt, and the processor 200 acquires the interrupt information from the previous target storage region when notified of the interrupt by the interrupt notifying section 238. Alternatively, the memory writing section 234 may switch the target storage region at the same time as the notification of the interrupt from the receiving section 232 or in response to an instruction from the processor 200.

The memory writing section 234 may sequentially write a plurality of pieces of interrupt information included in a plurality of sequentially received interrupt packets into the target storage region so that the pieces of interrupt information are buffered in the target storage region. When the receiving section 232 receives a plurality of interrupt packets, the receiving section 232 may receive a second interrupt packet before the interrupt notifying section 238 notifies the processor 200 of an interrupt corresponding to a first interrupt packet. In this case, the interrupt notifying section 238 may notify the processor 200 of an interrupt corresponding to both the first and second interrupt packets.

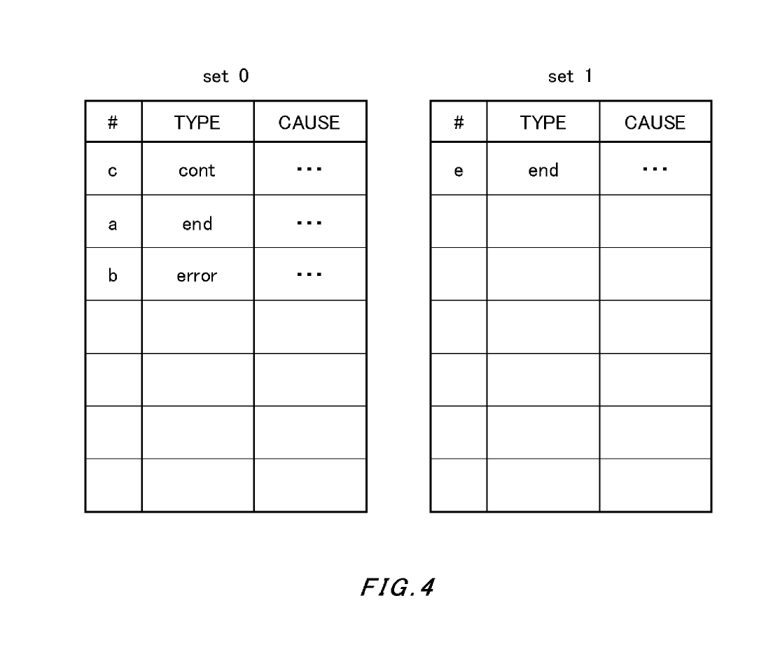

FIG. 4 illustrates, as an example, the interrupt information stored on the memory 220 of the test apparatus 100 relating to the embodiment of the present invention. The memory writing section 234 writes interrupt information into regions set 0 and set 1, which are represented as an example of the storage regions 225 of the memory 220. According to the present embodiment, the interrupt information stored on the storage regions 225 includes the number of a particular test module 150 that has issued the interrupt packet, the type of the interrupt, and the cause of the interrupt.

For example, when the receiving section 232 receives interrupt packets sequentially transmitted from test modules 150c, 150a, and 150b, the memory writing section 234 sequentially writes the pieces of interrupt information of the received interrupt packets into the target storage region, in this case, the storage region set 0 so that the pieces of interrupt information are buffered in the target storage region set 0. The memory writing section 234 may update the designation register 236 to switch the target storage region from the storage region set 0 to a different storage region, for example, the storage region set 1 in response to the interrupt notifying section 238 notifying the processor 200 of the interrupts. Alternatively, the memory writing section 234 may switch the target storage region at the same time as the notification of the interrupt from the receiving section 232 or in response to an instruction from the processor 200.

Here, the memory writing section 234 may have a pointer indicating an entry into which writing is to be performed. The memory writing section 234 may increment the value of the pointer when buffering interrupt information into the target storage region set 0. The memory writing section 234 may clear the pointer in response to the switching of the target storage region from the storage region set 0 to the different storage region set 1. Alternatively, the memory writing section 234 may clear the designation register 236 and/or the pointer in response to the processor 200 referencing the interrupt information.

Here, the memory writing section 234 may update the designation register 236 to switch the target storage region depending on whether the to-be-written interrupt information matches predetermined interrupt information. In this manner, the memory writing section 234 can classify the to-be-written interrupt information into an appropriate group, such that the processor 200 can reference appropriate interrupt information in accordance with the test programs. Here, a case is assumed where the processor 200 is notified of an interrupt while executing a high-priority operation. In this case, the processor 200 continues executing the high-priority operation, and may reference the buffered interrupt information after completing the operation or an appropriate portion of the operation.

Having the above-described configuration, the test apparatus 100 relating to the present embodiment can perform a plurality of tests on one or more devices under test 10 by using one or more test modules 150 with it being possible to keep track of the interrupt requests transmitted from the test modules 150. Because the test apparatus 100 can keep track of the interrupt requests from the test modules 150 while executing test programs, the test apparatus 100 can suspend or terminate the tests, perform a different type of tests, or modify test parameters as necessary in response to the interrupt requests.

The test apparatus 100 may cause one test controller 130 to start executing one test program with the use of one or more test modules 150 and to control the tests with reference to the interrupt requests from the test modules 150. Alternatively, the test apparatus 100 may cause one or more test controllers 130 to start executing one test program with the use of one or more test modules 150 and each test controller 130 may control the tests with reference to the interrupt requests from the test modules 150 connected thereto.

In other words, the test apparatus 100 relating to the present embodiment can execute the test program while maintaining the synchronization between the test modules 150, which are in a one-to-one correspondence with tests. Furthermore, the test apparatus 100 can perform a variety of tests, that is to say, can suspend or terminate the tests, perform a different type of tests, or modify test parameters as necessary in response to the interrupt requests issued by the individual test modules 150.

Although some aspects of the present invention have been described by way of exemplary embodiments, it should be understood that those skilled in the art might make many changes and substitutions without departing from the spirit and the scope of the present invention which is defined only by the appended claims.

The claims, specification and drawings describe the processes of an apparatus, a system, a program and a method by using the terms such as operations, procedures, steps and stages. When a reference is made to the execution order of the processes, wording such as “before” or “prior to” is not explicitly used. The processes may be performed in any order unless an output of a particular process is used by the following process. In the claims, specification and drawings, a flow of operations may be explained by using the terms such as “first” and “next” for the sake of convenience. This, however, does not necessarily indicate that the operations should be performed in the explained order.

What is claimed is:

1. A test apparatus for testing a device under test, comprising:
a test module that exchanges signals with the device under test to test the device under test;
a test controller that includes a processor and a memory, the test controller controlling the test module; and
a network that transfers communication packets between the test module and the test controller, wherein
the test controller includes:
a receiving section that receives an interrupt packet requesting an interrupt to the test controller, from the test module via the network;
a memory writing section that writes interrupt information included in the interrupt packet into the memory; and
an interrupt notifying section that notifies the processor of the interrupt to cause the processor to reference the interrupt information written into the memory.

2. The test apparatus as set forth in claim 1, wherein
when the receiving section receives a plurality of interrupt packets, the memory writing section sequentially writes a plurality of pieces of interrupt information included in the plurality of interrupt packets into the memory.

3. The test apparatus as set forth in claim 2, wherein
the processor references the memory to acquire the plurality of pieces of interrupt information when notified of the interrupts by the interrupt notifying section.

4. The test apparatus as set forth in claim 1, wherein
the memory has a plurality of storage regions for storing the interrupt information,
the memory writing section includes a designation register that designates one of the plurality of storage regions as a target storage region into which the interrupt information is to be written by the memory writing section,
the memory writing section updates the designation register to switch the target storage region to a different one of the plurality of storage regions when the interrupt notifying section notifies the processor of the interrupt, and
the processor acquires the interrupt information from the storage region that is designated as the target storage region before the switching, when notified of the interrupt by the interrupt notifying section.

5. The test apparatus as set forth in claim 4, wherein
the memory writing section sequentially writes a plurality of pieces of interrupt information included in a plurality of sequentially received interrupt packets into the target storage region so that the plurality of pieces of interrupt information are buffered in the target storage region.

6. The test apparatus as set forth in claim 1, wherein
when the receiving section receives a second interrupt packet before the interrupt notifying section notifies the processor of an interrupt corresponding to a first interrupt packet, the interrupt notifying section notifies the processor of an interrupt corresponding to both the first and second interrupt packets.

7. A test method for testing a device under test, comprising:
testing the device under test by transmitting/receiving signals to/from the device under test;
controlling the testing by using a processor and a memory; and
transferring communication packets between the testing and the controlling, wherein
the testing includes:
receiving an interrupt packet requesting an interrupt to the controlling from the testing via the transferring;
writing interrupt information included in the interrupt packet into the memory; and
notifying the processor of an interrupt to cause the processor to reference the interrupt information written into the memory.
